(19) United States
(12) Patent Application Publication
(10) Pub. No.: US 2024/0304458 A1
(43) Pub. Date: Sep. 12, 2024

(54) METHOD FOR MANUFACTURING SILICON WAFER AND SILICON WAFER

(71) Applicant: GLOBAL WAFERS JAPAN CO., LTD., Niigata (JP)

(72) Inventors: Susumu MAEDA, Kitakanbara-gun, Niigata (JP); Haruo SUDO, Kitakanbara-gun, Niigata (JP); Hisashi MATSUMURA, Kitakanbara-gun, Niigata (JP); Tatsuhiko AOKI, Kitakanbara-gun, Niigata (JP); Toru YAMASHITA, Kitakanbara-gun, Niigata (JP)

(73) Assignee: GLOBAL WAFERS JAPAN CO., LTD., Kitakanbara-gun, Niigata (JP)

(21) Appl. No.: 18/263,960

(22) PCT Filed: Feb. 15, 2022
(86) PCT No.: PCT/JP2022/005929

§ 371 Date: Aug. 2, 2023

(30) Foreign Application Priority Data
Feb. 25, 2021 (JP) 2021-028234

(51) Int. Cl. H01L 21/324; H01L 21/67

(52) U.S. Cl. CPC H01L 21/324; H01L 21/67115

(57) ABSTRACT

A clean silicon wafer, having a DZ layer free of micro-defects formed in a device active region on the surface of the thermally-processed silicon wafer, an IG layer having a high gettering capability formed in a bulk layer, and little heavy metal contamination on the wafer surface is manufactured. A method for manufacturing a silicon wafer for performing the rapid thermal process for a silicon wafer in a furnace, the method performs the rapid thermal process with a thermal budget of 53% or more and 65% or less, in terms of a thermal budget with temperature and time, when a condition where a thermal process at a highest temperature of 1350° C. is maintained for a predetermined longest holding time is taken as 100% of the thermal budget.

### TECHNICAL FIELD

The present invention relates to a method for manufacturing a silicon wafer and a silicon wafer, and relates to a method for manufacturing a silicon wafer including a defect-free layer (denuded zone (DZ) layer) on a surface layer thereof using a rapid thermal process (RTP) and an intrinsic gettering layer (IG layer) by oxygen precipitates in a bulk layer, and a silicon wafer.

### BACKGROUND ART

In a manufacturing process of a semiconductor device, a crystal originated particle (COP; void defect) existing in a device active region (approximately 10 μm in depth from the wafer surface) of a wafer may cause deterioration in characteristics and reliability of the semiconductor device.

As a method of eliminating the COP on the wafer surface layer, there is a method of performing a rapid thermal process (RTP) on a silicon wafer as disclosed in Patent Literature 1 (PTL 1).

The RTP is a process of heating a silicon wafer to a high temperature of 1000° C. or higher on a time scale of a few seconds or less. Such high-speed heating is performed by a high-intensity lamp or the like. In a cooling process, in order to prevent dislocation and wafer breakage due to thermal stress, control is generally performed so that the wafer temperature is slowly lowered.

According to this method, by subjecting the silicon wafer to the high-temperature thermal process, oxygen on the wafer surface is diffused outward to reduce interstitial oxygen, and oxygen-related defects such as an inner wall oxide film of a COP and oxygen precipitates of crystals are dissolved due to a non-saturated state of oxygen, thereby forming a defect-free layer (DZ layer) free of micro-defects in the device active region on the wafer surface.

Furthermore, in a deep region (bulk portion) below the DZ layer, excessive interstitial oxygen contained is precipitated by the high-temperature thermal process, and a bulk micro-defect (BMD) represented by micro-SiO₂ precipitates is generated. The BMD causes to occur distortion in the silicon matrix of the bulk portion to induce secondary dislocations and stacking faults, and getters metal impurities (an intrinsic gettering layer (IG layer) is formed).

### CITATION LIST

### Patent Literature

PTL 1: JP 2003-273049 A

### SUMMARY OF INVENTION

### Technical Problem

However, in a case where a thermal budget (total quantity of thermal processes) in the rapid thermal process (RTP) on a silicon wafer increases, heavy metal contamination such as iron (Fe) generated from a furnace body during the high-temperature thermal processing becomes significant on the wafer surface, which brings about a problem that the contamination causes quality deterioration such as white blemishes when a high-performance sensor such as a complementary metal oxide semiconductor (CMOS) contact image sensor (CIS) is used.

In addition, in a case where the thermal budget is large, a thermal load of a lamp that is a heating source in the RTP increases, and the lamp may be damaged.

In view of the above problems, the thermal budget in the RTP is desired to be as small as possible, but in such a case, there is a problem that it is not able to enjoy the advantages of the RTP because the COP remains on the wafer surface or the formation of the BMD in the bulk layer is not satisfactory.

An object of the present invention is to provide a method for manufacturing a silicon wafer and a silicon wafer, the method by which, when a silicon wafer is subjected to a rapid thermal process (RTP), the thermal process can be completed without damaging an RTP apparatus, and which allows manufacturing a clean silicon wafer, with little heavy metal contamination on the wafer surface, in which a DZ layer free of micro-defects is formed in a device active region on the surface of the thermally-processed silicon wafer, and an IG layer having a high gettering capability is formed in a bulk layer thereof.

### Solution to Problem

A method for manufacturing a silicon wafer according to the present invention, which has been made to solve the above problems, is a method for manufacturing a silicon wafer on which a rapid thermal process on a silicon wafer in a furnace is performed, the method including, in terms of the thermal budget with temperature and time, when a condition where a thermal process at a highest temperature of 1350° C. is maintained for a predetermined longest holding time is taken as 100% of the thermal budget, performing the rapid thermal process with the thermal budget of 53% or more and 65% or less.

An oxygen concentration of the wafer is controlled to be 0.6×10¹⁸ atoms/cm³ or more and 1.0×10¹⁸ atoms/cm³ or less (ASTM '79) for the silicon wafer to used in the rapid thermal process.

In the thermal process where the highest temperature of 1350° C. is maintained for the predetermined longest time, and the predetermined longest holding time is preferably 20 s.

In this manner, in the method for manufacturing a silicon wafer according to the present invention, in the rapid thermal process, when a case where the heating time at 1350° C., which is the highest heating temperature, for example, is 20 s, is defined as a thermal budget (total quantity of thermal process) of 100%, the silicon wafer is subjected to the thermal process with a thermal budget of 53% or more and 65% or less.

As a result, the thermal processing can be completed without damaging an RTP apparatus (such as lamps), and also the method allows the manufacturing of a clean silicon wafer, having a DZ layer free of micro-defects formed in a device active region on the surface of the thermally-processed silicon wafer, an IG layer having a high gettering capability formed in a bulk layer, and little heavy metal contamination on the wafer surface.

Further, a silicon wafer according to the present invention which has been made to solve the above problems, has the number of laser scattering tomography defects (LSTDs) on a surface layer of 0.3 numbers/cm² or less, and a BMD density of a bulk layer of 5×10¹⁰ cm⁻³ or more.

An oxygen concentration of the wafer is preferably 0.6×10¹⁸ atoms/cm³ or more and 1.0×10¹⁸ atoms/cm³ or less (ASTM '79).

### Advantageous Effects of Invention

According to the present invention, it is possible to provide a method for manufacturing a silicon wafer, by which, when a silicon wafer is subjected to a rapid thermal process (RTP), the thermal process can be completed without damaging an RTP device, and the method allows the manufacturing of a clean silicon wafer, having a DZ layer free of micro-defects formed in a device active region on the surface of the thermally-processed silicon wafer, an IG layer having a high gettering capability formed in a bulk layer, and little heavy metal contamination on the wafer surface.

### BRIEF DESCRIPTION OF DRAWINGS

FIG. 1 is a cross-sectional view illustrating an embodiment of a rapid thermal process device (RTP device) which is applied to a method for manufacturing a silicon wafer according to the present invention.

FIG. 2 is a graph illustrating an example of a thermal history of a silicon wafer to be applied in the rapid thermal process device (RTP device) in FIG. 1.

FIG. 3 is a graph illustrating the thermal history under condition No. 1 of an example.

FIG. 4 is a graph illustrating the thermal history under condition No. 2 of the example.

FIG. 5 is a graph illustrating the thermal history under condition No. 3 of the example.

FIG. 6 is a graph illustrating the thermal history under condition No. 4 of the example.

FIG. 7 is a graph illustrating the thermal history under condition No. 5 of the example.

FIG. 8 is a graph illustrating the thermal history under condition No. 6 of the example.

FIG. 9 is a graph illustrating the thermal history under condition No. 7 of the example.

FIG. 10 is a graph illustrating the thermal history under condition No. 8 of the example.

FIG. 11 is a graph illustrating the thermal history under condition No. 9 of the example.

FIG. 12 is a graph illustrating the thermal history under condition No. 10 of the example.

FIG. 13 is a graph illustrating the thermal history under condition No. 11 of the example.

FIG. 14 is a graph illustrating the thermal history under condition No. 12 of the example.

FIG. 15 is a graph illustrating the results of Experiment 1 and Experiment 2 of the example.

FIG. 16 is a graph illustrating the results of Experiment 3 of the example.

FIG. 17 is a graph illustrating the results of Experiment 4 and Experiment 5 of the example.

### DESCRIPTION OF EMBODIMENTS

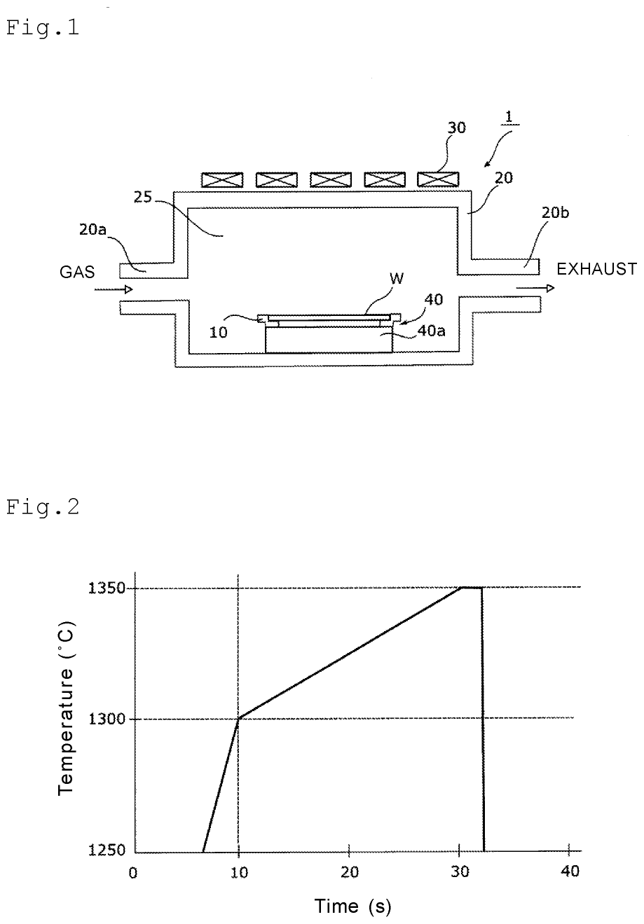

Hereinbelow, preferred embodiments of the present invention will be described based on the drawings. FIG. 1 is a cross-sectional view illustrating an embodiment of a rapid thermal process device (RTP device) which is applied to a method for manufacturing a silicon wafer according to the present invention.

As illustrated in FIG. 1, an RTP device 1 includes a chamber (reaction tube) 20 provided with an atmospheric gas inlet 20a and an atmospheric gas outlet 20b, a plurality of lamps 30 arranged at a distance from each other in an upper portion of the chamber 20, and a substrate support unit 40 that supports a silicon wafer W in a reaction space 25 in the chamber 20. In addition, a rotation means (not shown) that rotates the silicon wafer W at a predetermined speed around the central axis is provided.

The substrate support unit 40 includes a ring 10 that supports the outer periphery of the silicon wafer W and a stage 40a that supports the ring 10. The chamber 20 is made of quartz, for example. Each of the lamps 30 is a halogen lamp, for example. The stage 40a is made of quartz, for example. The RTP device 1 can uniformly heat and process the entire silicon wafer W with a temperature gradient of temperature rise and drop of 10 to 300° C./s, and a detailed thermal budget will be described below.

In the RTP device 1 according to the present embodiment, an average temperature for multiple points is measured (for example, 9 points) in the substrate plane in the substrate radial direction of the backside of the silicon wafer W with a plurality of radiation thermometers embedded in the stage 40a of the substrate support unit 40, and the temperature in the reaction space 25 is controlled by controlling the plurality of halogen lamps 30 (individual ON-OFF control of each of the lamps, control of emission intensity of light to be emitted, and the like) based on the measured temperature.

Next, a method for manufacturing a silicon wafer according to an embodiment will be described using the RTP device 1 in FIG. 1.

First, the silicon wafer W is placed and fixed on the ring 10. The ring 10 is fixed to the upper portion of the stage 40a which is installed in the reaction space 25 under an oxidizing atmosphere such that the upper surface of the silicon wafer W is substantially parallel to the upper portion thereof.

Process gas is introduced from the atmospheric gas inlet 20a, and the gas in the reaction space 25 is exhausted from the atmospheric gas outlet 20b, to form a predetermined airflow over the silicon wafer W.

Subsequently, the halogen lamps 30 arranged at equal spaces are individually controlled based on the feedback from the plurality of radiation thermometers embedded in the stage 40a, that is, based on the temperature of the backside of the silicon wafer W. Then, the silicon wafer W is heat-processed by rapidly heating the inside of the reaction space 25, while controlling the temperature of the silicon wafer W.

Here, in the RTP device 1 according to the present embodiment, a state where the thermal process at 1350° C., which is the highest heating temperature, is maintained for 20 s (longest time), for example, is taken as the thermal budget (total quantity of thermal process) of 100%, a rapid thermal process is performed with a thermal budget of 53% or more and 65% or less, for example.

For example, as illustrated in the graph of FIG. 2, the wafer surface temperature is raised to 1300° C. in 10 s after the start of heating.

Subsequently, the wafer surface temperature is raised to 1350° C. in 27 to 32 s after the start of heating, and this state is maintained for 0 to 6 s.

Thereafter, the inside of the furnace is rapidly cooled to complete the rapid thermal process.

In addition, the silicon wafer used in the rapid thermal process is prepared to have the oxygen concentration of the substrate of 0.6×10¹⁸ atoms/cm³ or more and 1.0×10¹⁸ atoms/cm³ or less (ASTM '79).

In such a rapid thermal process, by raising the heating temperature to 1350° C., COP on the wafer surface can be eliminated, and a DZ layer can be formed. In addition, the concentration of vacancies to be introduced is increased, which makes it possible to obtain a high BMD density enough for the bulk layer to have a sufficiently high gettering capability. In a case where the heating temperature does not reach 1350° C. (the thermal budget is insufficient), void defects remain on the wafer surface layer, and the BMD density of the bulk layer decreases, leading to the lowering of the gettering capability.

In addition, by not maintaining the heating time at 1350° C. long, which is the highest heating temperature, the Fe—B concentration measured with the surface photovoltage (SPV) method can be lowered (less than 1×10⁹ cm⁻³), and the silicon wafer can be kept clean. If the heating time at 1350° C. is too long and the thermal budget is too large, Fe contamination (heavy metal contamination) becomes pronounced, and the heat load on the RTP device 1 increases, which is not preferable because there might be a risk of lamp breakage or the like.

As described above, according to the embodiment of the present invention, when a case where the heating time at 1350° C., which is the highest heating temperature, for example, is 20 s, is taken as a thermal budget (total quantity of thermal process) of 100% in the rapid thermal process with the RTP device 1, the silicon wafer is subjected to the thermal process with a thermal budget of 53% or more and 65% or less.

As a result, the thermal process can be completed without damaging the RTP device, and the method allows the manufacturing of a clean silicon wafer, having a DZ layer free of micro-defects formed in a device active region on the surface of the thermally-processed silicon wafer, an IG layer having a high gettering capability formed in a bulk layer, and little heavy metal contamination on the wafer surface.

In the above embodiment, the highest temperature of 1350° C. is maintained for several seconds, and the preferred ratio of the thermal budget is adjusted. However, the present invention is not limited to this mode, and the ratio of the thermal budget may be adjusted to 53% or more and 65% or less by gradually lowering the temperature without maintaining the highest temperature of 1350° C., for example.

Further, in the above embodiment, the holding time at the highest temperature is set to 20 s in the rapid thermal process, but the present invention is not limited thereto, and a time longer than 20 s may be set as the highest-temperature holding time.

### EXAMPLES

The method for manufacturing a silicon wafer and the silicon wafer according to the present invention will be further described based on examples. In the present example, the following experiments were performed based on the above embodiment.

### Experiment 1

In Experiment 1, the number of laser scattering tomography defects (LSTD) (micro-defects such as COP detected by laser light scattering) was measured by changing the conditions of the rapid thermal process for the silicon wafer. The silicon wafer used in the rapid thermal process has an oxygen concentration of the substrate of approximately 1.0×10¹⁸ atoms/cm³ (ASTM '79).

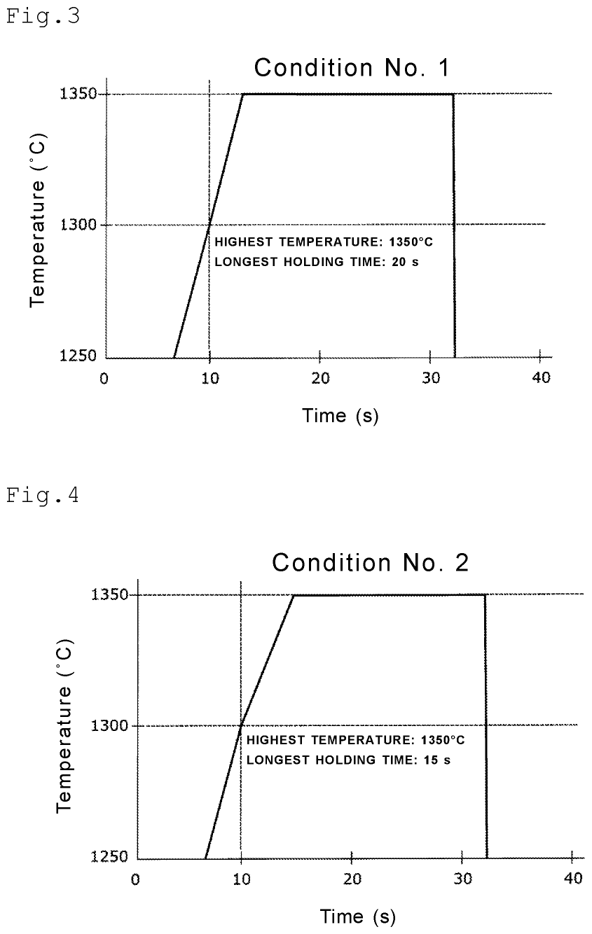

In condition No. 1, the thermal history as illustrated in FIG. 3 was employed, the highest temperature was 1350° C., and the highest-temperature holding time was 20 s. This condition was set to be the thermal budget of 100%.

In condition No. 2, the thermal history as illustrated in FIG. 4 was employed, the highest temperature was 1350° C., and the highest-temperature holding time was 15 s. The thermal budget under this condition was 92.9%.

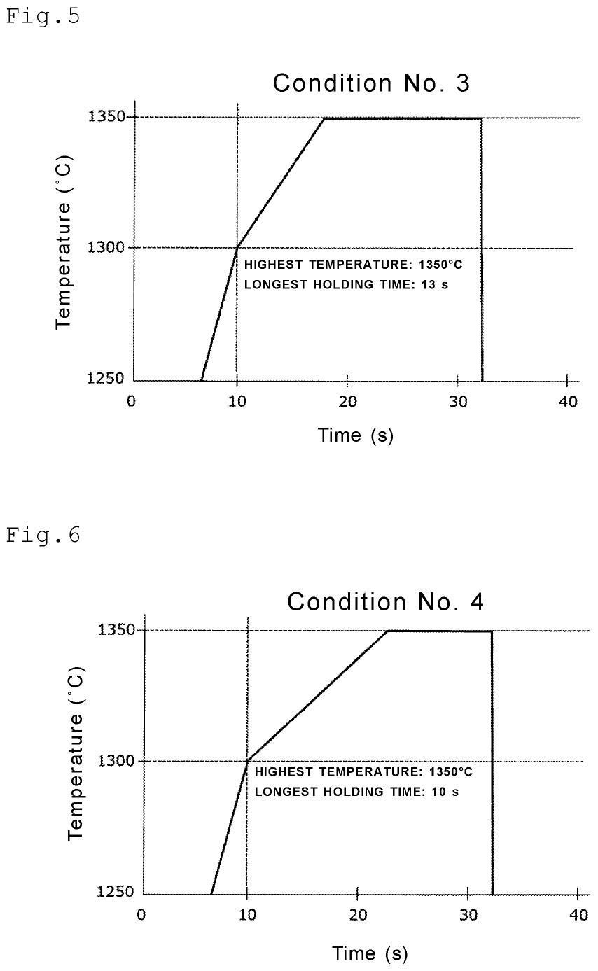

In condition No. 3, the thermal history as illustrated in FIG. 5 was employed, the highest temperature was 1350° C., and the highest-temperature holding time was 13 s. The thermal budget under this condition was 85.1%.

In condition No. 4, the thermal history as illustrated in FIG. 6 was employed, the highest temperature was 1350° C., and the highest-temperature holding time was 10 s. The thermal budget under this condition was 75.2%.

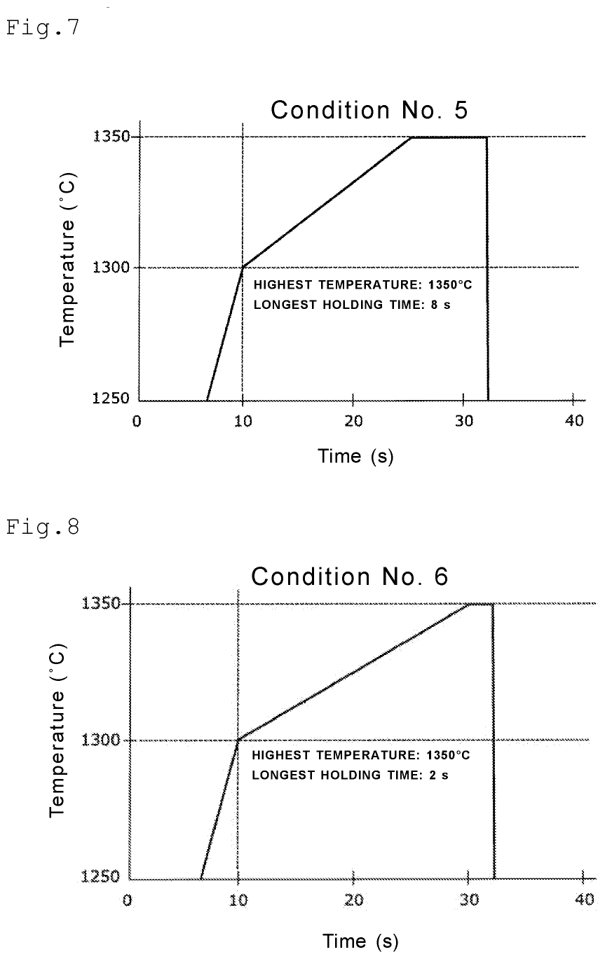

In condition No. 5, the thermal history as illustrated in FIG. 7 was employed, the highest temperature was 1350° C., and the highest-temperature holding time was 8 s. The thermal budget under this condition was 65.4%.

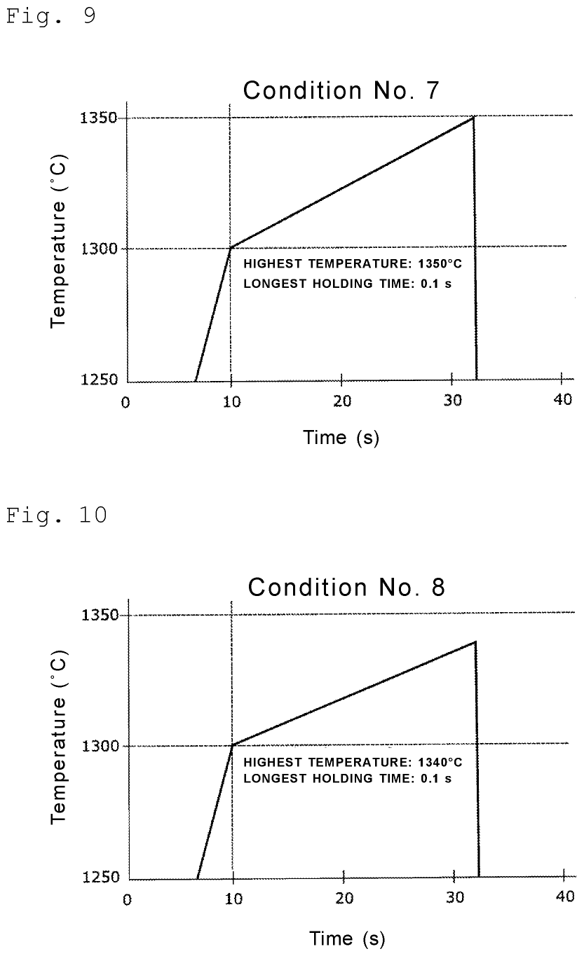

In condition No. 6, the thermal history as illustrated in FIG. 8 was employed, the highest temperature was 1350° C., and the highest-temperature holding time was 2 s. The thermal budget under this condition was 59.4%.

In condition No. 7, the thermal history as illustrated in FIG. 9 was employed, the highest temperature was 1350° C., and the highest-temperature holding time was 0.1 s. The thermal budget under this condition was 52.8%.

In condition No. 8, the thermal history as illustrated in FIG. 10 was employed, the highest temperature was 1340° C., and the highest-temperature holding time was 0.1 s. The thermal budget under this condition was 42.3%.

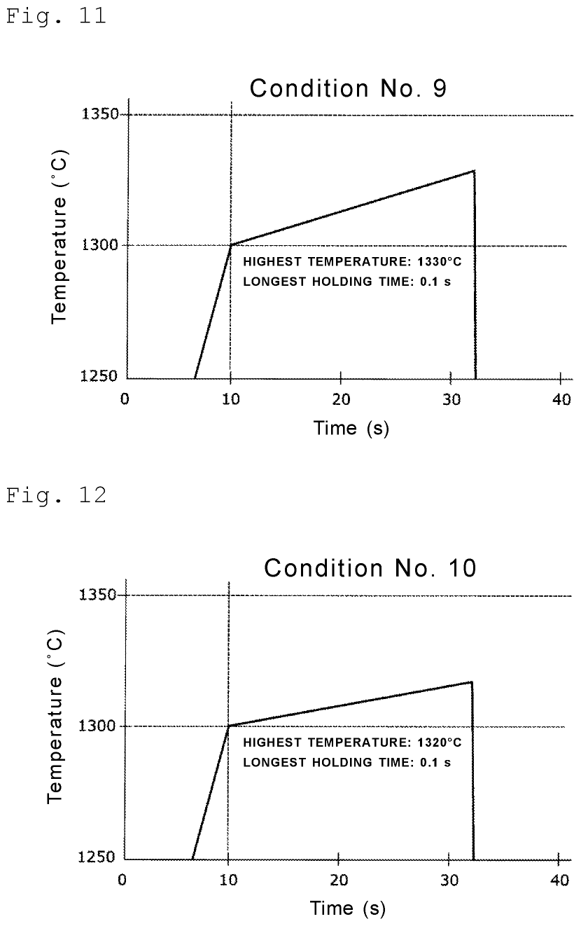

In condition No. 9, the thermal history as illustrated in FIG. 11 was employed, the highest temperature was 1330° C., and the highest-temperature holding time was 0.1 s. The thermal budget under this condition was 31.7%.

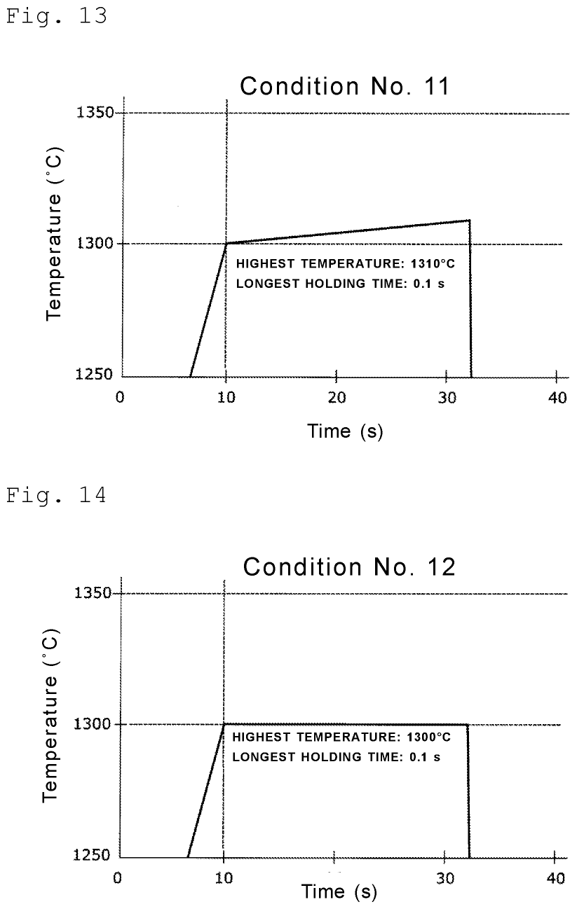

In condition No. 10, the thermal history as illustrated in FIG. 12 was employed, the highest temperature was 1320° C., and the highest-temperature holding time was 0.1 s. The thermal budget under this condition was 21.1%.

In condition No. 11, the thermal history as illustrated in FIG. 13 was employed, the highest temperature was 1310° C., and the highest-temperature holding time was 0.1 s. The thermal budget under this condition was 10.5%.

In condition No. 12, the thermal history as illustrated in FIG. 14 was employed, the highest temperature was 1300° C., and the highest-temperature holding time was 22 s. The thermal budget under this condition was 0%.

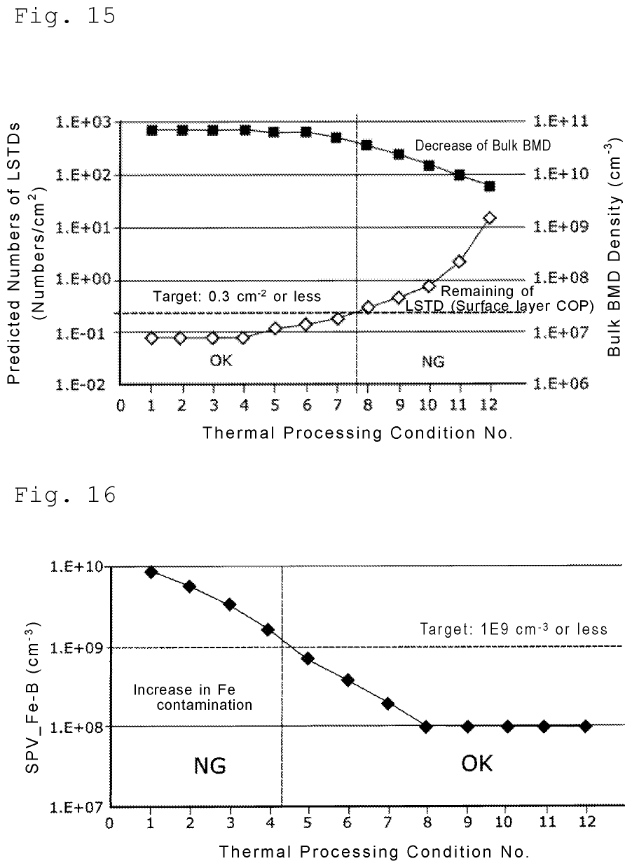

The graph in FIG. 15 illustrates the results under conditions No. 1 to No. 12. In the graph in FIG. 15, the vertical axis (left-hand side) represents the predicted number of LSTDs (numbers/cm²), and the horizontal axis represents the condition number.

As illustrated in this graph, the number of LSTDs has increased with decreasing thermal budget from conditions No. 1 to No. 12. In and after condition No. 8, the number of LSTDs exceeds 0.3 numbers/cm², showing worse values. Therefore, it is found that conditions No. 1 to No. 7 are favorable as the thermal process conditions for eliminating the COPS on the wafer surface layer.

### Experiment 2

In Experiment 2, the BMD density of the bulk layer was measured under the same conditions of the rapid thermal process as in Experiment 1.

The graph in FIG. 15 illustrates the results under conditions No. 1 to No. 12. In the graph in FIG. 15, the vertical axis (right-hand side) represents the BMD density (cm⁻³) of the bulk layer, and the horizontal axis represents the condition number.

As illustrated in this graph, under conditions No. 1 to No. 7, the BMD density of the bulk layer is substantially constant, and a sufficiently high value (5×1010 cm⁻³ or more) is obtained.

However, in and after condition No. 8, the BMD density of the bulk layer has decreased with decreasing thermal budget. The reason for this is that the concentration of vacancies introduced in the rapid thermal process decreases with decreasing thermal budget.

Therefore, it is found that conditions No. 1 to No. 7 are favorable as the thermal process conditions for the bulk layer to have a sufficiently high gettering capability.

### Experiment 3

In Experiment 3, the Fe—B concentration of the thermally-processed silicon wafer was measured by the SPV method under the same conditions of the rapid thermal process as in Experiment 1.

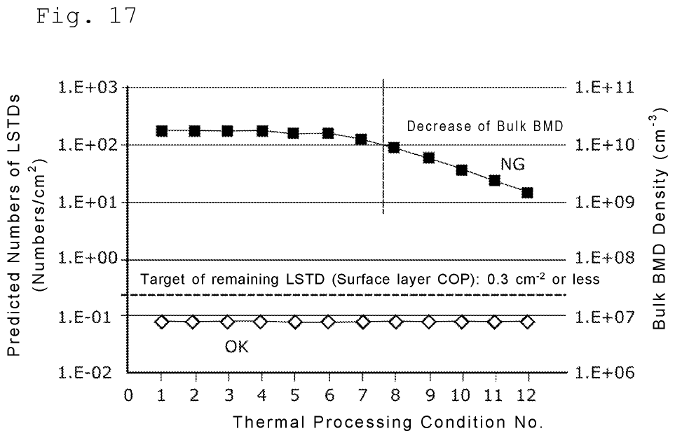

The graph in FIG. 16 illustrates the results under conditions No. 1 to No. 12. In the graph in FIG. 16, the vertical axis represents the Fe—B concentration (cm⁻³), and the horizontal axis represents the condition number.

As illustrated in this graph, the Fe—B concentration gradually decreases from conditions No. 1 to No. 8, and in and after condition No. 8, the Fe—B concentration is equal to or less than the measurement lower limit value. Let the preferable Fe—B concentration be 1×10⁹ cm⁻³, the concentration less than this value is obtained under conditions No. 5 to No. 12.

Therefore, it is found that conditions No. 5 to No. 12 are preferable to process cleanly of the silicon wafers.

From the results of Experiments 1 to 3 described above, it is found that in a case where the oxygen concentration of the substrate is approximately 1.0×10¹⁸ atoms/cm³ (ASTM '79), the thermal process conditions under which the COP on the wafer surface layer can be eliminated, the gettering capability of the bulk layer is sufficient, and the silicon wafer can be cleanly processed are conditions No. 5 (thermal budget 65%) to No. 7 (thermal budget 53%).

In addition, in the range of conditions No. 5 to No. 7, the highest-temperature holding time is not too long, a sufficient thermal budget can be secured, and adverse effects on the RTP device can be suppressed.

### Experiment 4

In Experiment 4, similarly to Experiment 1, the number of micro-defects such as COP detected by laser light scattering (LSTD) was measured by changing the conditions of the rapid thermal process for the silicon wafer.

In Experiment 4, only the oxygen concentration of the silicon wafer substrate used in the rapid thermal process is different from that in Experiment 1, and the value thereof is approximately 0.6×10¹⁸ atoms/cm³ (ASTM '79).

The graph in FIG. 17 illustrates the results under conditions No. 1 to No. 12. In the graph in FIG. 17, the vertical axis (left-hand side) represents the predicted number of LSTDs (numbers/cm²), and the horizontal axis represents condition numbers.

As illustrated in this graph, the number of LSTDs is 0.3 numbers/cm² or less which is the target value under conditions No. 1 to No. 12.

### Experiment 5

In Experiment 5, the BMD density of the bulk layer was measured under the same conditions of the rapid thermal process as in Experiment 4.

The graph in FIG. 17 illustrates the results under conditions No. 1 to No. 12. In the graph in FIG. 17, the vertical axis (right-hand side) represents the BMD density (cm⁻³) of the bulk layer, and the horizontal axis represents the condition numbers.

As illustrated in this graph, under conditions No. 1 to No. 7, the BMD density of the bulk layer is substantially constant, and a sufficiently high value (5×10¹⁰ cm⁻³ or more) is obtained.

However, in and after condition No. 8, the BMD density of the bulk layer decreases with decreasing thermal budget.

Therefore, it is found that conditions No. 1 to No. 7 are favorable as the thermal process conditions for the sufficient gettering capability of the bulk layer.

From the results of Experiments 4 and 5 described above, even when the oxygen concentration of the substrate is approximately 0.6×10¹⁸ atoms/cm³ (ASTM '79), it is confirmed that under conditions No. 1 to No. 7, the number of LSTDs in the wafer surface layer can be suppressed and the gettering performance of the bulk layer is sufficient. Therefore, the oxygen concentration of the substrate is desirably 0.6×10¹⁸ atoms/cm³ or more and 1.0×10¹⁸ atoms/cm³ or less (ASTM '79).

### INDUSTRIAL APPLICABILITY

As described above, the method for manufacturing a silicon wafer according to the present invention is useful for a silicon wafer requiring high quality and is particularly suitable for rapid thermal processing (RTP) of silicon wafers.

### REFERENCE SIGNS LIST

1 RTP device
20 chamber (furnace)
25 reaction space
30 halogen lamp (lamp)
40 substrate support unit
40a stage
W silicon wafer

1. A method for manufacturing a silicon wafer, for performing a rapid thermal process on a silicon wafer in a chamber, the method comprising:
in terms of a thermal budget with temperature and time, when a condition where a thermal process at a highest temperature of 1350° C. is maintained for a predetermined longest holding time is taken as 100% of the thermal budget,
performing the rapid thermal process with a thermal budget of 53% or more and 65% or less.

2. The method for manufacturing a silicon wafer according to claim 1, wherein an oxygen concentration of the wafer is controlled to be 0.6×10¹⁸ atoms/cm³ or more and 1.0×10¹⁸ atoms/cm³ or less (ASTM '79) for the silicon wafer to be used in the rapid thermal process.

3. The method for manufacturing a silicon wafer according to claim 1, wherein, in the thermal process where the highest temperature of 1350° C. is maintained for the predetermined longest time, the predetermined longest holding time is 20 s.

4. A silicon wafer having the number of LSTDs on a surface layer of 0.3 numbers/cm² or less, and having a BMD density of a bulk layer is 5×10¹⁰ cm⁻³ or more.

5. The silicon wafer according to claim 4, wherein an oxygen concentration of the wafer is 0.6×10¹⁸ atoms/cm³ or more and 1.0×10¹⁸ atoms/cm³ or less (ASTM '79).
